(19) United States
(12) Patent Application Publication
(10) Pub. No.: US 2017/0033247 A1
(43) Pub. Date: Feb. 2, 2017

(54) FLEXIBLE ANTENNA INTEGRATED WITH AN ARRAY OF SOLAR CELLS

(71) Applicant: The Regents of the University of Michigan, Ann arbor, MI (US)

(72) Inventors: Kamal Sarabandi, Ann Arbor, MI (US); Kyusang Lee, Ann Arbor, MI (US); Stephen R. Forrest, Ann Arbor, MI (US); Jungsuek Oh, Richardson, TX (US)

(21) Appl. No.: 15/302,277

(22) PCT Filed: Apr. 29, 2015
(86) PCT No.: PCT/US2015/028273

§ 371 Date: Oct. 6, 2016

Related U.S. Application Data
(60) Provisional application No. 61/985,649, filed on Apr. 29, 2014.

(51) Int. Cl. H01L 31/046; B64C 39/02; B64C 33/00; H01L 31/18; H01Q 9/04

(52) U.S. Cl. CPC H01L 31/046; H01L 31/184; H01L 31/1868; H01Q 9/0421; B64C 33/00; B64C 39/028; B64C 2201/025; B64C 2201/066

(57) ABSTRACT

A device comprising a thin film solar cell with an integrated flexible antenna, such as a meander line antenna, is disclosed. In an embodiment, the device comprises a substrate and an array of solar cells disposed on the substrate, wherein the array of solar cells are interconnected by metal conductors that carry DC power from the solar cells and which form at least part of the flexible antenna. In their capacity as an antenna, the metal conductors operate cooperatively with the solar cells to radiate an RF signal, receive an RF signal, or both radiate and receive an RF signal. The device optionally comprises a choke disposed on the substrate and electrically coupled to the array of solar cells, wherein the choke operates to impede conduction of the RF signal. A method of making the disclosed device is also disclosed.

### CROSS-REFERENCE TO RELATED APPLICATION

This application claims the benefit of U.S. Provisional Application No. 61/985,649, filed Apr. 29, 2014, which is incorporated herein by reference in its entirety.

### STATEMENT REGARDING FEDERALLY SPONSORED RESEARCH

This invention was made with government support under contract W911NF-08-2-0004 awarded by the U.S. Army Research Laboratory. The Government has certain rights in the invention.

### JOINT RESEARCH AGREEMENT

The subject matter of the present disclosure was made by, on behalf of, and/or in connection with one or more of the following parties to a joint university-corporation research agreement: The Regents of the University of Michigan and NanoFlex Power Corporation. The agreement was in effect on and before the date the subject matter of the present disclosure was prepared, and was made as a result of activities undertaken within the scope of the agreement.

The present disclosure generally relates to a flexible antenna integrated with an array of solar cells.

Rapid developments in thin film optoelectronic devices have accelerated the application of flexible electronics, propelled by the increasing demand for lighter and smaller products with lower power consumption. Twistable and foldable devices promise new functionality for many applications in areas such as communication, displays and health care. For example, a user with a flexible mobile phone may only need to twist the appliance to dismiss a call, or change a program. Foldable devices such as flexible keyboards and displays can provide portability and save space when not in operation. In this context, flexible antennas also address a wide range of applications in wireless communication when they are integrated with conformal electronics platforms.

In view of the foregoing, there is disclosed flexible electronics that can be applied to a variety of devices, such as consumer electronics, and micro-unmanned autonomous robots that have significant demands for small size, weight, and power (SWaP). Such systems often require a power supply that is sufficient to complete a mission, which may be realized using an array of photovoltaic cells. For example, the required power supply can be accomplished by covering the exposed upper surfaces of robotic flyers with light-weight, thin and flexible solar cells.

The SWaP requirements can also be efficiently met by including multi-functionality among different system components. For example, such robots often need wireless transceivers operating at ultrahigh frequencies (UHF). Hence, multi-functionality is achieved by integrating the UHF antenna with the solar cells on the robot wing. Early studies regarding the integration of antennas with solar cells concentrated on stacking the two components in efficient ways, considering the two components as physically separated parts. Recently, efforts to utilize solar cells as radiating elements for size reduction in the integrated structure have been reported. However, the integrated packages that consist of brittle and heavy solar cells are too bulky to be practical for robotic flappers.

There is presented herein the fabrication and measurement of a conformal planar antenna integrated with a flexible, durable and light weight thin film GaAs solar cells mounted on a device to be powered, such as the wing of a flapping robot. The UHF antenna is designed to allow for the placement of centimeter-size solar cells in series with metallic traces of the antenna. The antenna operates with both small and large signals, and its performance is unaffected by the rectifying solar cell. Further, the integrated circuit does not limit the motion of the robot wings. Antenna impedance and radiation characteristics are found to be comparable to those of a similarly configured discrete component.

In view of the foregoing, there is disclosed a device comprising a thin-film solar cell with an integrated flexible antenna. In an embodiment, the device comprises a substrate and an array of solar cells disposed on the substrate, wherein the array of solar cells are interconnected by metal conductors that carry DC power from the solar cells and which form at least part of the flexible antenna. In their capacity as an antenna, the metal conductors operate cooperatively with the solar cells to radiate an RF signal, receive an RF signal, or both radiate and receive an RF signal. The device optionally comprises a choke disposed on the substrate and electrically coupled to the array of solar cells, wherein the choke operates to impede conduction of the RF signal.

There is also disclosed a method of making the disclosed device comprising a thin-film solar cell integrated with a flexible antenna. In one embodiment, the method comprises providing a growth substrate; depositing at least one protection layer on the growth substrate; depositing at least one sacrificial layer on the at least one protection layer; depositing at least one photoactive cell on the sacrificial layer; forming a patterned metal layer comprising an array of mesas on the photoactive cells by a photolithography method; bonding the patterned metal layer to a metallized surface of a plastic sheet, etching the sacrificial layer with one or more etch steps that remove the photoactive cell from the growth substrate to form thin film solar cells; and depositing metal conductors that are attached to the solar cells and which form a flexible antenna.

It is to be understood that both the foregoing general description and the following detailed description are exemplary and explanatory only and are not restrictive of the invention, as claimed.

### BRIEF DESCRIPTION OF THE DRAWINGS

The accompanying figures, which are incorporated in and constitute a part of this specification, illustrate several embodiments of the invention and together with the description, serve to explain the principles of the invention.

FIG. 1 is a diagram of an example embodiment of a flexible antenna integrated with a thin-film solar cell array.

FIG. 2A is a circuit layout for example embodiment of the integrated solar cell array and antenna.

FIG. 2B is a diagram depicting an example RF choke design for use in the flexible antenna.

FIG. 2C is a cross-sectional schematic of the solar cell structure connected to antenna metallic traces.

FIG. 3 is a graph illustrating current density-voltage characteristics of a discrete solar cell and two solar cells in series.

FIGS. 4A and 4B are graphs illustrating measured real and imaginary parts, respectively, of the input impedance of the thin-film solar cell in the presence/absence of illumination.

FIG. 5 is a graph illustrating measured and simulated S₁₁ parameter of the antenna under illumination.

FIG. 6 is a graph illustrating measured S₁₁ under illumination and in the dark.

FIG. 7 is a graph illustrating measured S₁₁ for floating or connected DC output.

FIG. 8 is a diagram depicting current distribution on the antenna when one DC output is grounded.

FIG. 9 is a graph illustrating measured S₁₁ for the antenna placed over Styrofoam cylinders with two different radii of curvatures (8 cm and 11 cm); the results are also compared to the flat case.

FIGS. 10A and 10B are graphs illustrating simulated and measured, respectively, co and cross-polarization radiation patterns in the E(yz)-plane.

The drawings described herein are for illustrative purposes only of selected embodiments and not all possible implementations, and are not intended to limit the scope of the present disclosure. Corresponding reference numerals indicate corresponding parts throughout the several views of the drawings.

### DETAILED DESCRIPTION

### Definitions

As used herein, the term “thin-film” refers to layers having thickness that range from a few nanometers (nm) to tens of micrometers (μm).

As used herein, the term “thin-film solar cell” refers to an organic-based solar cell that comprises a series of very thin vapor or solution deposited organic layers. Such layers have thickness that vary from a few nanometers (nm) to tens of micrometers (μm). While not a requirement, thin-film solar cells are typically flexible.

As used herein, the term “III-V material,” may be used to refer to compound crystals containing elements from group IIIA and group VA of the periodic table. More specifically, the term “III-V material” may be used herein to refer to compounds which are combinations of the group of Gallium (Ga), Indium (In) and Aluminum (Al), and the group of Arsenic (As), Phosphorous (P), Nitrogen (N), and Antimony (Sb).

It should be noted that the III-V compounds herein are named in an abbreviated format. A two component material is considered to be in approximately a 1:1 molar ratio of group III:V compounds. In a three or more component system (e.g. InGaAlAsP), the sum of the group III species (i.e. In, Ga, and Al) is approximately 1 and the sum of the group V components (i.e. As, and P) is approximately 1, and thus the ratio of group III to group V is approximately unity.

Names of III-V compounds are assumed to be in the stoichiometric ratio needed to achieve lattice matching or lattice mismatching (strain), as inferred from the surrounding text. Additionally, names can be transposed to some degree. For example, AlGaAs and GaAlAs are the same material.

As used and depicted herein, a “layer” refers to a member or component of a device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

When a first layer is described as disposed or deposited “over” or “above” a second layer, the first layer is positioned further away from the substrate than the second layer. The first layer may be disposed directly on the second layer, but unless it is specified that the first layer is disposed or deposited “on” or “in physical contact with” the second layer, there may be other layers between the first layer and the second layer. For example, an epilayer may be described as disposed “over” or “above” a sacrificial layer, even though there may be various layers in between. Similarly, a protection layer may be described as disposed “over” or “above” a growth substrate, even though there may be various layers in between. Similarly, when a first layer is described as disposed or deposited “between” a second layer and a third layer, there may be other layers between the first layer and the second layer, and/or the first layer and the third layer, unless it is specified that the first layer is disposed or deposited “on” or “in physical contact with” the second and/or third layers.

As used herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

As used herein, the terms “wafer” and “growth substrate” can be used interchangeably.

Described herein is a device comprising a thin-film solar cell with an integrated flexible antenna, such as a meander line antenna. In an embodiment, the device comprises a substrate and an array of solar cells disposed on the substrate, wherein the array of solar cells are interconnected by metal conductors that carry DC power from the solar cells and which form at least part of the flexible antenna. The metal conductors operate cooperatively with the solar cells to radiate an RF signal, receive an RF signal, or both radiate and receive an RF signal.

In one embodiment, the metal conductors that interconnect the solar cells comprise at least one sputtered metal layer, such as Au ranging from 10-20 μm, with 15 μm being noted. To insure a conformal coating of these interconnected layers, sputtering may occur through a shadow mask.

The device optionally comprises a choke disposed on the substrate and electrically coupled to the array of solar cells, wherein the choke operates to impede conduction of the RF signal. In one embodiment, the choke is disposed between the array of solar cells and the metal conductors in the DC path.

In one embodiment, the device further comprises an energy store, such as a capacitor, electrically connected via the choke to the array of solar cells.

As described in more detail below, the thin film antenna integrated with a flexible solar cell array may be suitable for communication and for supplying power to a device, such as an unmanned vehicle, a robot, or consumer electronic device. In one embodiment, the unmanned vehicle comprises an aerial vehicle, or robotic flying device, wherein the robotic flyer comprises flappers which comprise the platform for the thin film solar cell and integrated flexible antenna.

In one embodiment, the device described herein further comprises at least one of a radio transmitter or a radio receiver electrical connected to the array of solar cells.

The flexible solar cell used in such a device may be fabricated on a growth wafer, and removed using a non-destructive epitaxial lift off (ND-ELO) process that eliminates wafer damage by employing surface protecting layers interposed between the wafer and the epitaxial structure. In one embodiment, the surface protection layers comprise a multilayer structure, including sequential protection, sacrificial and active device layers. The protection layers comprise protection and buffer layers, which are generally lattice matched layers having a thickness ranging from 5 to 200 nm, such as 10 to 150 nm, or even 20 to 100 nm. These layers are generally grown by gas source, such as gas source molecular beam epitaxy (GSMBE). Other suitable deposition techniques for preparing the growth structure include, but are not limited to, metallo-organic chemical vapor deposition (MOCVD), hydride vapor phase epitaxy (HVPE), solid source molecular beam epitaxy (SSMBE), and chemical beam epitaxy.

In one embodiment, the substrate may comprise GaAs, and the substrate protective layers and device structure protective layers may be lattice matched compounds, such as AlAs, GaAs, AlInP, GaInP, AlGaAs, GaPSb, AlPSb and combinations thereof. In another embodiment, the substrate may comprise GaAs and the substrate protective layers and device structure protective layers may be strained layers, such as InP, InGaAs, InAlAs, AlInP, GaInP, InAs, InSb, GaP, AlP, GaSb, AlSb and combinations thereof, including combinations with lattice matched compounds.

Examples of suitable III-V materials for the one or more protective layers include, but are not limited to, AlInP, GaInP, AlGaAs, GaPSb, AlPSb, InP, InGaAs, InAs, InSb, GaP, AlP, GaSb, AlSb, InAlAs, GaAsSb, AlAsSb, and GaAs. In some embodiments, when the growth substrate is GaAs, the one or more protective layers are chosen from lattice matched AlInP, GaInP, AlGaAs, GaPSb, AlPSb, and strained InP, InGaAs, AlInP, GaInP, InAs, InSb, GaP, AlP, GaSb, AlSb. In some embodiments, when the growth substrate is InP, the one or more protective layers are chosen from lattice matched InGaAs, InAlAs, GaAsSb, AlAsSb, and strained InGaAs, InAlAs, GaAsSb, AlAsSb, InAs, GaSb, AlSb, GaAs, GaP and AlP. U.S. Pat. No. 8,378,385 and U.S. Patent Publication No. 2013/0043214 are incorporated herein by reference for their disclosure of protective layer schemes.

The protection layer may further comprise one or more protective layers, as described. In some embodiments, the protection layer further comprises one protective layer. In other embodiments, the protection layer further comprises two protective layers. In other embodiments, the protection layer further comprises three or more protective layers. The protective layer(s) may be positioned between the growth substrate and the sacrificial layer.

A sacrificial release layer is then grown onto the protection layers. One non-limiting example of such a layer is AlAs. When using this material as a sacrificial layer, arsenic oxide buildup can slow the AlAs etch during lift-off. Thus, by cladding the Al(Ga)As with a slowly etched III-V material (e.g. InAlP, AlGaAs, InAlGaP) the arsenic oxide buildup can be reduced; thus, expediting the lift-off process. U.S. Patent Publication No. 2010/0047959, which is incorporated herein by reference, describes a method for selectively freeing an epitaxial layer from a single crystal substrate.

In one embodiment, the active thin-film device region can be lifted-off by selectively etching a sacrificial layer using a known acid. The sacrificial layer of the growth structure acts as a release layer during ELO for releasing the epilayer from the growth substrate. The sacrificial layer may be chosen to have a high etch selectivity relative to the epilayer and/or the growth substrate so as to minimize or eliminate the potential to damage the epilayer and/or growth substrate during ELO. It is also possible to use protective layers between the sacrificial layer and the epilayer to protect the epilayer during ELO. In some embodiments, the sacrificial layer comprises a III-V material. In some embodiments, the III-V material is chosen from AlAs, AlGaAs, AlInP, and AlGaInP. In certain embodiments, the sacrificial layer comprises Al(Ga)As. In some embodiments, the sacrificial layer has a thickness in a range from about 2 nm to about 200 nm, such as from about 4 nm to about 100 nm, from about 4 nm to about 80 nm, or from about 4 nm to about 25 nm.

The step of releasing the sacrificial layer by etching may be combined with other techniques, for example, spalling. PCT Patent Application No. PCT/US14/52642 is incorporated herein by reference for its disclosure of releasing an epilayer via combination of etching and spalling.

Next, the epilayer (or active device region) is grown, typically in inverted order such that after bonding to the secondary plastic substrate, devices can be fabricated in their conventional orientation, thereby eliminating a second transfer step often employed in ELO device processing. The epilayer of the growth structure refers any number of layers desired to be “lifted off” of the growth substrate. The epilayer, for example, may comprise any number of active semiconductor layers for fabricating an electronic or optoelectronic device. Thus, the epilayer is sometimes referred to as an “active device region.” The epilayer may comprise layers for fabricating devices including, but not limited to, photovoltaics, photodiodes, light-emitting diodes, and field effect transistors, such as metal-semiconductor field-effect-transistors and high-electron-mobility transistors. In some embodiments, the epilayer comprises at least one III-V material.

In one embodiment, after the substrate is bonded to the plastic substrate, the active device region may be lifted-off from the parent wafer by immersion etching, such as with an acid.

In one embodiment, the photovoltaic cell comprises an active photovoltaic region comprising a flexible crystalline semiconducting cell. Non-limiting examples of the single junction semiconducting cell includes InGaP, GaAs, InGaAs, InP, or InAlP. The flexible crystalline semiconducting cell typically has a thickness ranging from 2 to 10 μm, such as from 3-6 μm.

In another embodiment, the photovoltaic cell comprising an active photovoltaic region comprising multi-junctions cells, such as tandem photovoltaic (with two sub-cells), triple junction cells (three sub-cells), or even quad junction cells (four sub-cells).

After the photovoltaic cell is formed, it is coated with a conductive metal coating on one surface. Non-limiting examples of the metal coating includes at least one metal chosen from Au, Ag, Pt, Pd, Ni, and Cu, with a particular emphasis on Au. In one embodiment, the Au layer on the support substrate has a thickness ranging from 100-500 nm, such as from 200-400 nm.

Once the photovoltaic cell is removed from the growth substrate by the non-destruction ELO process described above, it is mounted on the support structure by various bonding process. For example, the active photovoltaic region, whether single junction or multi-junction cells, may be applied to the host substrate by a direct-attachment bonding process. This process comprises adding metal layers to adjoining surfaces of the active region and the flexible host substrate and using cold-welding to bond them. Cold-weld bonding processes typically include pressing two surfaces together at room temperature to achieve a uniformly bonded interface.

Alternative direct-attachment bonding processes may include thermo-compression bonding, which typically involves the application of a lower pressure but at a high temperature (i.e., higher than the metal re-crystallization temperature). This process is typically not used when the flexible substrate has a glass transition and/or a melting temperature below the re-crystallization temperature of metal layers used in direct-attachment bonding processes.

Another direct-attachment technique for bonding metal layers associated with an ELO process that may be used is a thermally-assisted cold-weld bonding process using a lower pressure than typical cold-welding processes and a lower temperature than typical thermo-compression bonding processes. Particularly, thermally-assisted cold-welding may reduce the likelihood of damaging semiconductor wafers, thereby increasing the reuse rate of the wafers for growing additional active regions.

Non-limiting examples of the direct-attachment bonding processes that can be used herein include cold-welding, thermally assisted cold-welding, or thermo-compression bonding. U.S. Patent Application Publication No. US 2013/0037095, which describes cold-welding, is incorporated herein by reference.

In one embodiment, the thin-film solar cells described herein have lateral dimensions of about 1 cm, and are modeled as a capacitor that efficiently conducts RF signal. The RF circuit properties are unaffected by illumination. The meander planar antenna described herein incorporates solar cells that are integrated with an RF choke to allow for conduction of DC power while limiting the condition of the RF signal. The performance of the antenna is shown below as being tested under various bending conditions with minimal degradation to the antenna resonant frequency, return loss and solar cell power generation characteristics.

It is envisioned that a thin film antenna integrated with a flexible solar cell array may be used to supply power to a flapping wing robot. Flapping wings that propel the miniature robotic flyer have a large area surface that can be exposed to solar radiation. Hence, they provide a platform for mounting photovoltaic cells that can supply energy as long as the embedded electronics present an acceptably small load on the flapper itself.

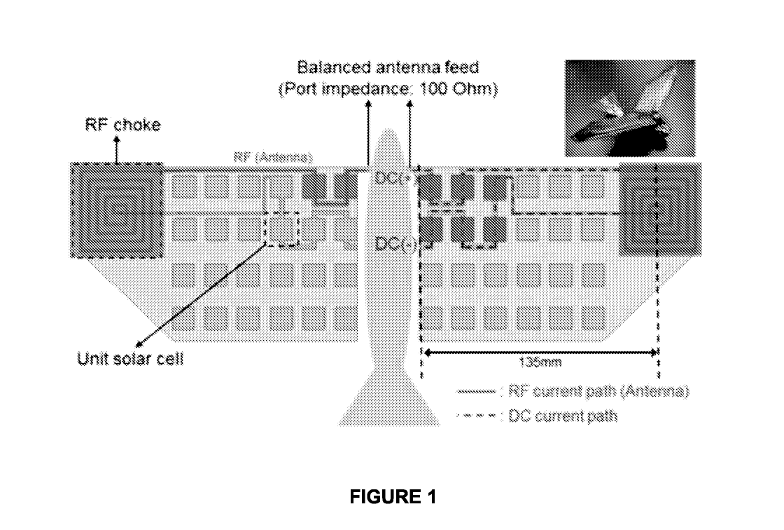

FIG. 1 shows a robotic platform and integrated circuit layout on the wing according to one embodiment. The circuit comprises a flexible antenna incorporating solar cell array and a spiral RF choke. To test the feasibility of the integrated antenna and solar cells, fabricated solar cells are transferred to the antenna circuit. At the end of the wing, the RF choke blocks RF currents excited by the antenna. While reference is made to a robotic flyer, the flexible antenna system with an integrated array of solar cells is suitable for other applications as well.

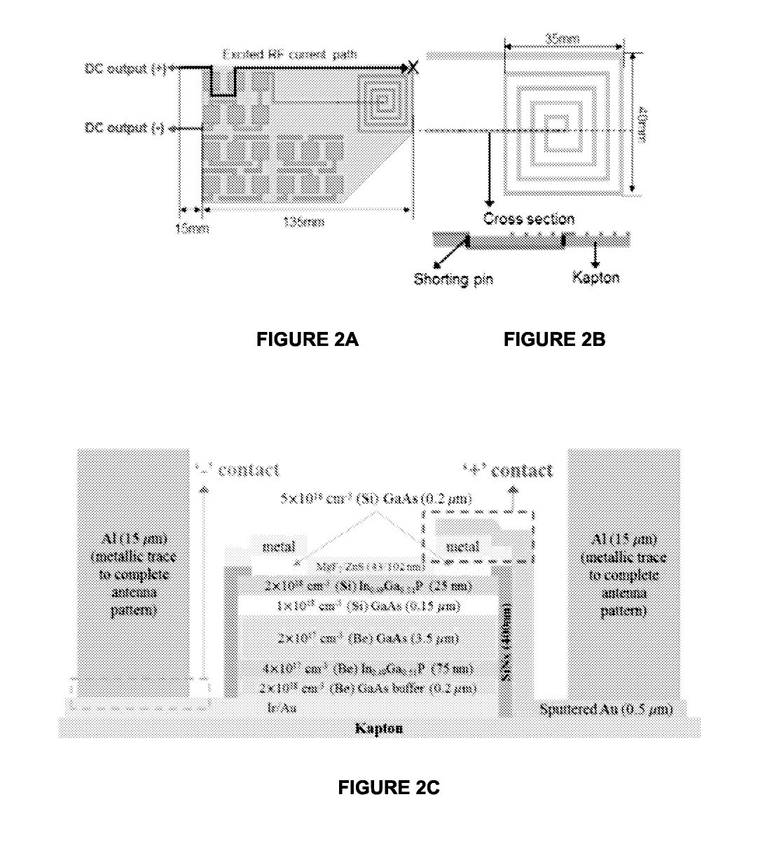

FIG. 2(a) shows the RF and DC power current paths of an example flexible antenna system according to one embodiment. Here, the thin-film solar cell capacitance conducts the RF current and introduces a small phase shift similar to that incurred in a similar circuit configuration but lacking the photovoltaics.

FIG. 2(b) shows the top and side views of the RF choke with vertical pins connecting the conductor in the center of the spiral to one on the reverse side of the thin substrate web according to one embodiment. The top and lower metallic conductors are then connected to DC output pads.

FIG. 2(c) shows a cross-sectional view of an epitaxial lift-off solar cell bonded to the Kapton® sheet according to one embodiment. In this embodiment, the robot body, the antenna feed where both RF and DC current exist is split to two current paths. One is connected to RF module through DC block and the other is connected to battery through RF choke.

To maximize power generation from a limited area, in one embodiment, a single crystalline III-V compound semiconductor solar cell can be employed. The fabrication of single GaAs thin film solar cells has been discussed previously; however, to develop a solar cell array, the wire bonding technology was developed to be compatible with the thin film devices. Therefore, previous thin film GaAs solar cell fabrication techniques can be modified to include an interconnection that enables the integration of all components on a thin, flexible plastic substrate. While reference is made below to particular materials and manufacturing processes, other types of materials and/or processes fall within the broader aspects of this disclosure.

In an example embodiment, the solar cell structure can be grown using gas source molecular beam epitaxy followed by transfer via pressure cold welding to a substrate comprised of a thin flexible layer disposed on a sacrificial layer. In one embodiment, the flexible layer is a polyimide film (e.g., the Kapton®). Flexible layers comprised from other materials are also contemplated including Si, CIS, GIGS, CZTS, CZTSS, CdTe, a-Si, thin-film poly Si and the like. The broader aspects may be extended to other types of flexible materials as well including but not limited to cloth, vinyl, silk, leather, for example. The heavy and brittle sacrificial layer is then removed, for example by epitaxial lift off (ELO), leaving behind only the thin and lightweight GaAs solar cell active region. The transferred thin film is next fabricated into solar cells and connected in series to supply power to the robot. Finally, the antenna and RF choke are patterned using vacuum thermal evaporation of Au through a shadow mask.

The devices and methods described herein will be further described by the following non-limiting examples, which are intended to be purely exemplary.

### Example

In this example, a conformal planar antenna integrated with a flexible, durable and light weight thin film GaAs solar cells. More specifically, a 0.2 μm thick, Be-doped GaAs buffer layer was grown on a Zn-doped (100) GaAs wafer, followed by a 40 nm thick undoped AlAs sacrificial layer. The layer thicknesses and doping of each layer of the full epitaxial layer structure is shown in FIG. 2(c). A 4 nm thick Iridium (IR) adhesion layer was sputtered at 8.5 mTorr base pressure on a 50 μm thick Kapton® sheet. Then a 1 μm thick Au layer was deposited on both the Kapton® and the epitaxial layer surface using electron beam deposition. These two surfaces were then bonded by cold-welding by applying pressure to the structure with the two Au layers in contact. The epitaxial layers were then lifted off by etching the sacrificial layer in a 10% HF solution.

Solar cell fabrication comprised depositing a Ni(5 nm)/Ge(50 nm)/Au(0.8 μm) grid onto the n-type surface by e-beam evaporation, and then patterned using photolithography and lift-off. The (1 cm)² solar cell mesas were defined using photolithography and wet-etching of the GaAs active layer. Then, Au was wet-etched (TFA etchant, Transene CO), followed by an IR inductive coupled plasma etch using 9 sccm of Cl₂ gas at 4 mTorr for 9 sec to pattern the back-side metal array interconnects. The contacts were annealed for 1 hr at 180° C. The top GaAs layer that lies outside the metal contact area was removed by wet etching. The conventional wire bonding technology, which uses heat, pressure and ultrasonic energy, was incompatible with plastic substrate mounting due to the substrate softness and low tolerance to elevated temperatures. To alleviate this problem, metal sputtering was employed to deposit interconnections, enabling conformal coating through passivated sidewalls combined with patterned rear side metal connection, which was described above. To allow for series connection of the solar cells, the sides of each solar cell were passivated using a 400 nm SiNx layer deposited by plasma enhanced chemical vapor deposition and patterned by photolithography and plasma etching. After a ZnS(43 nm)/MgF₂(102 nm) anti-reflective coating was deposited by e-beam evaporation, solar cells were connected in series using a 0.5 μm thick Au layer sputtered through a shadow-mask. Other techniques for connecting the solar cells that could have been used include evaporation of metal over passivation layer, cold-weld binding or wire bonding. These techniques provide a robust thin film interconnection for the integration of multiple components on a flexible plastic substrate.

After solar cell fabrication, a 15 μm thick Al layer was deposited using a shadow mask and e-beam evaporation to form the antenna and RF choke. Then, the DC output metal connection was evaporated onto the reverse side of the Kapton® sheet and connected to both the center of the RF choke and the contact pad on front side. Considering the fact that the skin depth of Al at 350 MHz was about 4 μm, the thickness of the Al layer was chosen to be 15 μm (>3 skin depth) to ensure high antenna efficiency.

Characteristics of Thin-Film Solar Cells

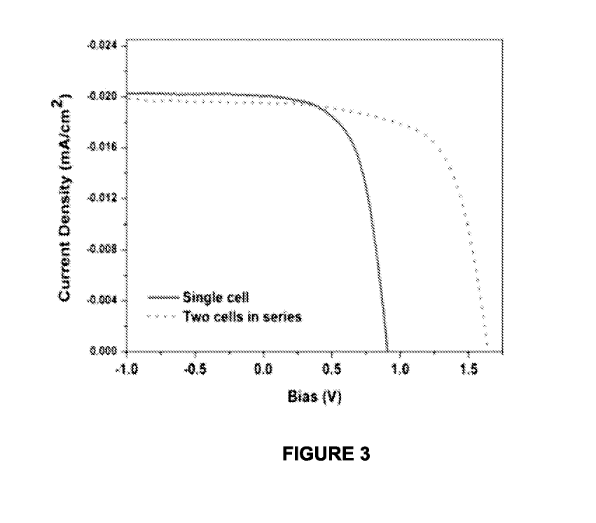

To demonstrate the effectiveness of power generation and the multi-functionality of device, the current density-voltage (J-V) characteristics of the GaAs photovoltaic cell and a series array of two cells were measured under simulated AM1.5G spectrum, 1 sun intensity (100 mW/cm²) illumination. The resulting properties are shown in FIG. 3. The optical power intensity was calibrated using a National Renewable Energy Laboratory certified Si reference photovoltaic cell. The cell short circuit current density was 19.5±0.6 mA/cm² and the open circuit voltage was 0.90±0.01 V with a fill factor of 55±4% resulting in a power conversion efficiency of 10±1%. The short circuit current density for the array was 19.4 mA/cm² and the open circuit voltage was 1.64 V with a fill factor of 64%.

Impedance Characteristics of Thin-Film Solar Cells

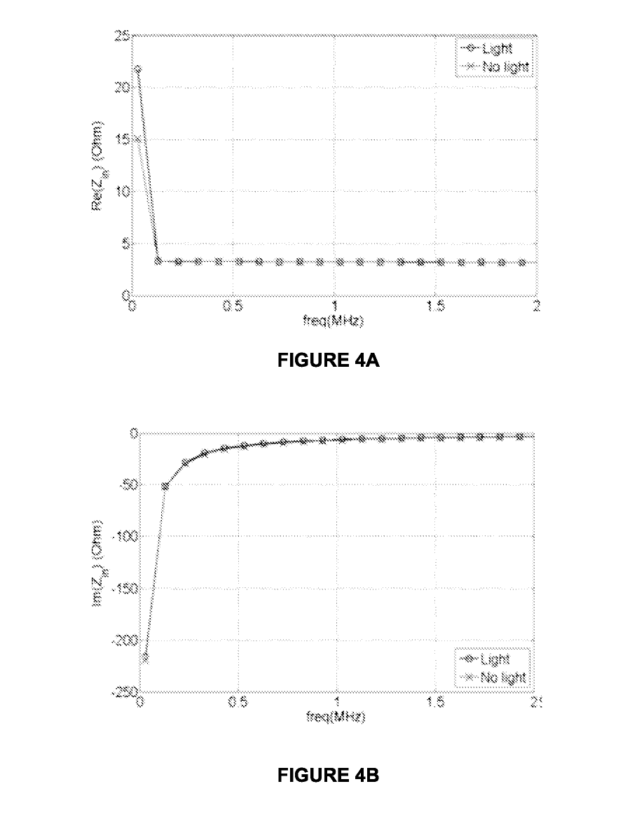

To employ the thin-film solar cell as a part of an efficient antenna, the effect of the solar cell on the RF antenna characteristics was first qualified. The input impedance of the 1 cm² solar cell was measured with a vector network analyzer, where the contacts (see FIG. 2(c)) were connected by wirebonds to signal and ground. Using the measured S₁₁, the real and imaginary parts of the input impedance (Zn) of the solar cell were calculated under illumination and in the dark. FIGS. 4(a) and 4(b) indicated that the AC impedance was unaffected by illumination. As frequency increased, both the real and imaginary parts of Zᵢₙ approached zero. This suggests that the solar cell acts as an AC short due to its high junction capacitance.

Antenna Characteristics

As shown in FIGS. 1 and 2(c), the antenna allows conduction of the RF current through the thin-film solar cells. Due to the series configuration of the cells, the antenna geometry on two wings resembled a meander dipole loaded by RF chokes at the end. The RF chokes stopped the flow of RF current but allowed the conduction of the DC current to be used for powering other functions of the robot. A monopole version of the actual meander dipole antenna integrated with other components was employed for assessing various antenna performance characteristics such as input impedance, bending test, and radiation pattern measurements using an un-balanced feed.

The input impedance of monopole antenna mounted on large ground plane (>λ/2 where λ is the free-space wavelength) was half of that of dipole antenna. Here, 100.0Ω and 50.0Ω were used as source impedances of the dipole and monopole antennas, respectively. In addition, the use of a large ground plane (600 mm×600 mm) for the monopole was equivalent to a potential null surface existing between two arms of the actual dipole version. A balanced feed for dipole antennas produced a null surface in the plane bisecting the dipole structure. In this plane, any metallic structure like the antenna feed can be inserted without affecting the antenna characteristics. Therefore, in flapping robotic platforms, positioning components in the middle of two arms of the meander dipole antenna did not affect the performance of the antenna.

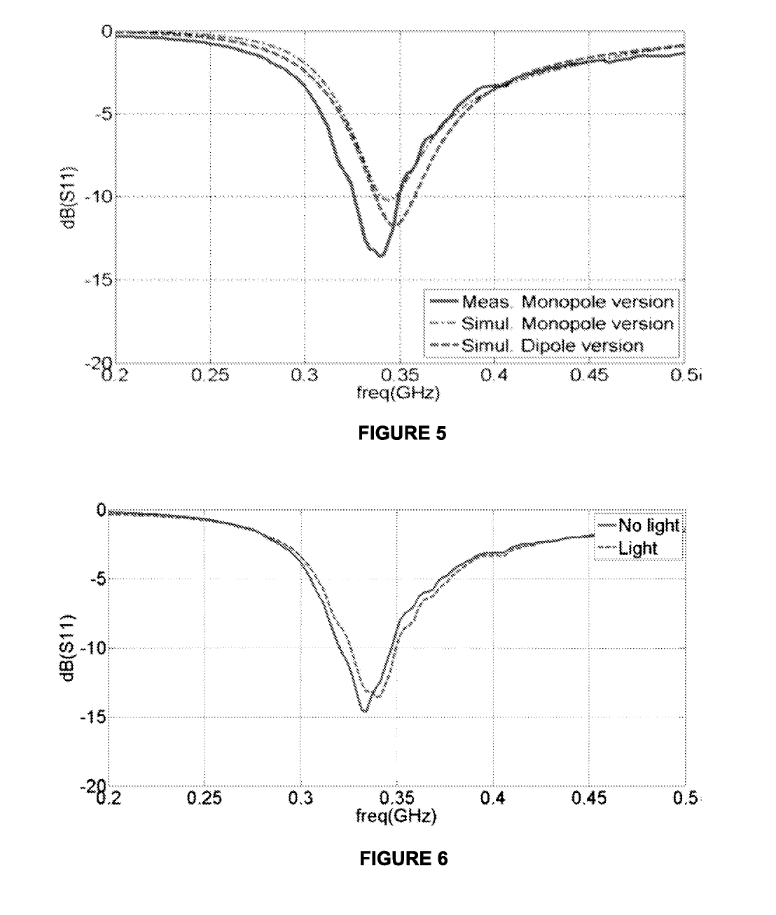

Since each thin-film solar cell was the AC equivalent to a metallic pad with the same dimension as the solar cell, the length of the dipole was adjusted so that the total current path length is λ₀/4, where λ₀ is the free-space wavelength at the antenna operating frequency, as shown in FIG. 2a. It was assumed that the effect of the thin (50 μm) Kapton sheet can be ignored at the operating frequency (350 MHz). To determine the junction capacitance of the thin-film solar cell, the areas occupied by the solar cells were replaced with gold pads. The simulated S₁₁ using Ansoft HFSS 13.0 by Ansys® was compared to the measured value of the antenna with solar cells under illumination, with results shown in FIG. 5. Agreement between measurements with and without the solar cells indicated that the solar cells did not influence the RF antenna performance. FIG. 6 shows the measured S₁₁ of the integrated solar cells and UHF antenna under illumination and in the dark. Apparently, the RF performance of the antenna was also unaffected by illumination.

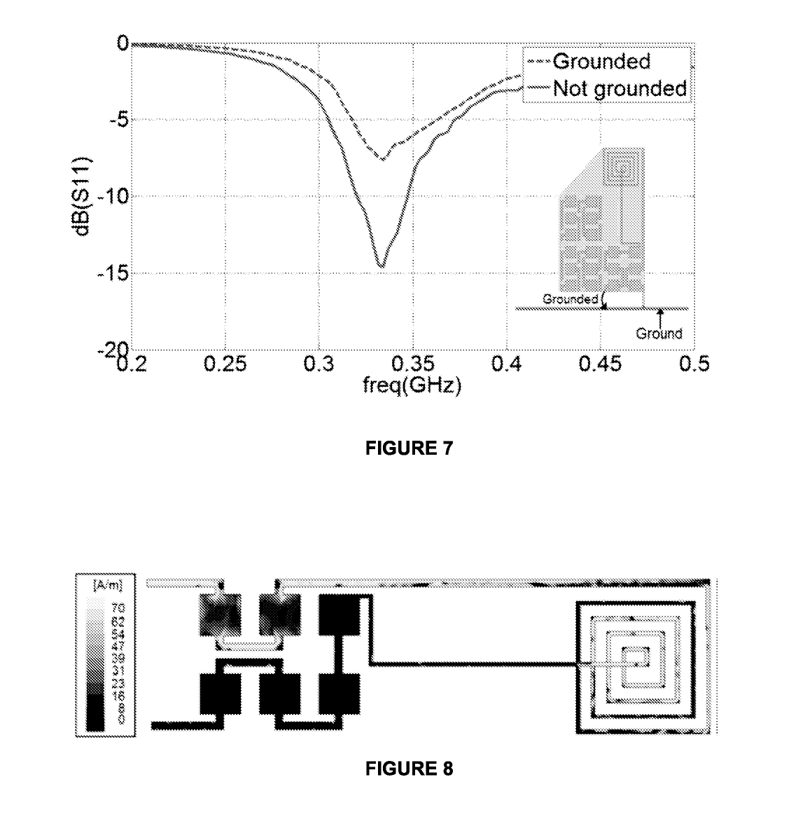

To test the RF choke operation, one of the DC outputs was grounded. FIG. 7 shows that while this caused a small change in impedance matching, the antenna operating (resonant) frequency remained unaffected. The change in input impedance was due to the limited inductance of the spiral inductor, and this change could have been reduced by increasing the number of turns in the inductor.

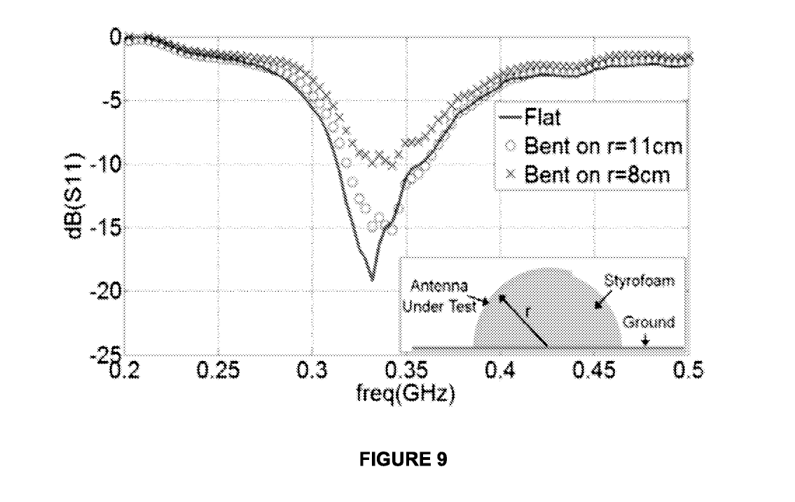

FIG. 8 shows current distribution in the antenna with one of the DC outputs grounded. The RF current was confined over the antenna and RF choke, and did not couple to the DC path. Also, changes in S₁₁ were measured under two bending conditions (see FIG. 9). The fabricated antenna was placed over Styrofoam cylinders with two different radii of curvature (8 cm and 11 cm). While the impedance was slightly changed due to varying parasitic coupling between the antenna and other metallic pathways on the solar cell array, changes in S₁₁ were sufficiently small to allow for reliable communications.

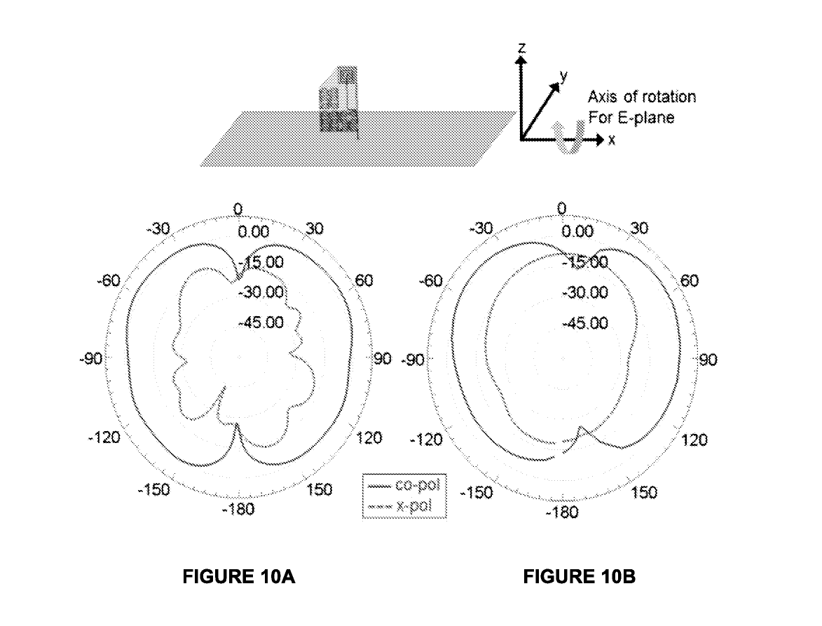

Finally, FIGS. 10A and 10B indicate that the measured radiation pattern of the antenna (FIG. 10B) agreed with the simulated radiation patterns (FIG. 10A), suggesting the operation of a monopole antenna with high efficiency of about 90%. In addition, as expected, the ratio of co- to cross-polarized radiation in the azimuthal plane (θ=90°, was relatively high (more than 10 dB).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed. As used herein, the term “and/or” includes any and all combinations of one or more of the associated listed items.

The description of the embodiments herein had been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A device comprising a thin-film solar cell with an integrated flexible antenna, said device comprising:
a substrate; and
an array of solar cells disposed on the substrate,
wherein the array of solar cells are interconnected by metal conductors that carry DC power from the solar cells, and which form at least part of the flexible antenna such that the metal conductors operate cooperatively with the solar cells to radiate an RF signal, receive an RF signal, or both radiate and receive an RF signal.

2. The device of claim 1, wherein at least a portion of the solar cells in the array of solar cells operate to convert solar energy into electrical energy concurrently with radiating and/or receiving the RF signal.

3. The device of claim 1, wherein the metal conductors and the array of solar cells form a meander line antenna.

4. The device of claim 1, further comprising a choke disposed on the substrate and electrically coupled to the array of solar cells, wherein the choke operates to impede conduction of the RF signal.

5. The device of claim 4, wherein the choke is disposed between the array of solar cells and the metal conductors in the DC path.

6. The device of claim 5, further comprising an energy store electrically connected via the choke to the array of solar cells.

7. The device of claim 1, wherein the substrate comprises a flexible polyimide film.

8. The device of claim 1, wherein solar cells in the array of solar cells are bonded to the substrate by direct attachment, wherein the substrate includes a plastic film on a sacrificial layer.

9. The device of claim 8, wherein said direct attachment comprises cold-welding, thermally assisted cold-welding, or thermo-compression bonding.

10. The device of claim 8, wherein the sacrificial layer is removed by a lift off process after the solar cells are transferred to the substrate.

11. The device of claim 8, wherein the metal conductors comprise at least one sputtered layer.

12. The device of claim 11, wherein then solar cells have terminals attached to the metal conductors via metal sputtering through a shadow mask.

13. The device of claim 1, further comprising at least one of a radio transmitter or a radio receiver electrical connected to the array of solar cells.

14. The device of claim 1, said device comprising an unmanned vehicle, a robot, or a consumer electronic device.

15. The device of claim 1, wherein said unmanned vehicles comprises an aerial vehicle or a robotic flying device, wherein said robotic flying device comprises flappers which comprise the platform for the thin film solar cell and integrated flexible antenna.

16. A method for forming a device comprising a thin-film solar cell integrated with a flexible antenna, said method comprising:
providing a growth substrate;
depositing at least one protection layer on the growth substrate;
depositing at least one sacrificial layer on the at least one protection layer;
depositing at least one photoactive cell on the sacrificial layer;
forming a patterned metal layer comprising an array of mesas on the photoactive cells by a photolithography method;
bonding the patterned metal layer to a metallized surface of a plastic sheet,
etching the sacrificial layer with one or more etch steps that remove the photoactive cell from the growth substrate to form thin-film solar cells; and
depositing metal conductors that are attached to the solar cells and which form a flexible antenna.

17. The method of claim 16, further comprising depositing at least one RF choke between the solar cells and the metal conductors.

18. The method of claim 17, wherein the metal conductors and RF choke are deposited using a shadow mask and at least one thin film deposition method.

19. The method of claim 18, wherein the at least one thin film deposition method comprises e-beam evaporation.

20. The method of claim 18, wherein the metal conductors and RF choke comprise an Al layer having a thickness ranging from 10-20 μm.

21. The method of claim 16, further comprising connecting the thin-film solar cells to a device to be powered by the solar cells.

22. The method of claim 16, wherein the growth substrate comprises GaAs or InP.

23. The method of claim 16, wherein the at least one protection layer is lattice matched with the growth substrate.

24. The method of claim 23, wherein the at least one protection layer is selected from AlAs, GaAs, InP, InGaAs, AlInP, GaInP, InAs, InSb, GaP, AlP, GaSb, AlSb, and combinations thereof.

25. The method of claim 16, wherein at least one of the protection layer, sacrificial layer, or photoactive cell is deposited by at least one process chosen from gas source molecular beam epitaxy (GSMBE), metallo-organic chemical vapor deposition (MOCVD), hydride vapor phase epitaxy (HVPE), solid source molecular beam epitaxy (SSMBE), and chemical beam epitaxy

26. The method of claim 16, wherein the at least one protection layer comprises a buffer layer, an etch-stop layer, or combinations thereof.

27. The method of claim 16, wherein said photolithography method comprises depositing a metal layer on the at least one photoactive cell; depositing a mask on top of the metal layer for mesa etching; and performing at least one etch step through said mask to form a pattern in the metal layer.

28. The method of claim 27, wherein said pattern extends to the sacrificial layer.

29. The method of claim 27, wherein the at least one etch step comprises contacting the sacrificial layer with a wet etchant, a dry etchant, or combinations thereof.

30. The method of claim 29, wherein said wet etchant comprises HF, H₃PO₄, HCl, H₂SO₄, H₂O₂, HNO₃, C₆H₈O₇, and combinations thereof, including combinations with H₂O.

31. The method of claim 29, wherein said dry etchant comprises reactive ion etching (RIE) with a plasma.

32. The method of claim 30, wherein the sacrificial layer comprises AlAs, and the one or more second etch steps comprise contacting said AlAs with HF.

33. The method of claim 16, wherein the photoactive cell is deposited on the growth substrate in an inverted manner.

34. The method of claim 16, wherein the at least one solar cell comprises a single junction or multi-junction cell.

35. The method of claim 16, wherein said bonding comprises a direct attachment method selected from cold-welding, thermally assisted cold-welding, or thermo-compression bonding to form a patterned solar cell bonded to a plastic sheet.
